(19) United States
(12) Patent Application Publication
(10) Pub. No.: US 2006/0176083 A1
(43) Pub. Date: Aug. 10, 2006

(54) Single ended three transistor quasi-static ram cell

(76) Inventor: Goran Krilic, Zagreb (HR)

Correspondence Address: DAVID A. GUERRA;INTERNATION PATENT GROUP, LLC, 10TH FLOOR, 610 8TH AVENUE S.W., CALGARY, AB, T2P 1G5, CA

(21) Appl. No.: 10/549,780

(22) PCT Filed: Mar. 21, 2003
(86) PCT No.: PCT/IB03/01078

§ 371 Date: Sep. 19, 2005

(51) Int. Cl. G01R 19/00

(52) U.S. Cl. 327/51

(57) ABSTRACT

A single ended three transistor quasi-static RAM cell comprises two cross coupled MOS transistors and one select MOS transistor connected to drain of one of the aforementioned MOS transistors wherein drains of both cross coupled MOS transistors are each connected to anode of one of two PN diodes functioning as constant current loads when exposed to continuous light from LED diode.

The cell has two stable states and and has only one port for data input/output. New solution is also introduction of light to PN junctions (diodes) which convert them in photodiodes. Photodiodes are constant current sources if exposed to continuous light. Furthermore it is object of this invention to show feasibility of manufacturing the memory cell using standard CMOS technology and occupying area of only four MOS transistors (3 active and one converted to two photodiodes). Power consumption of the cell in standby mode is small and it is only caused by photocurrent.

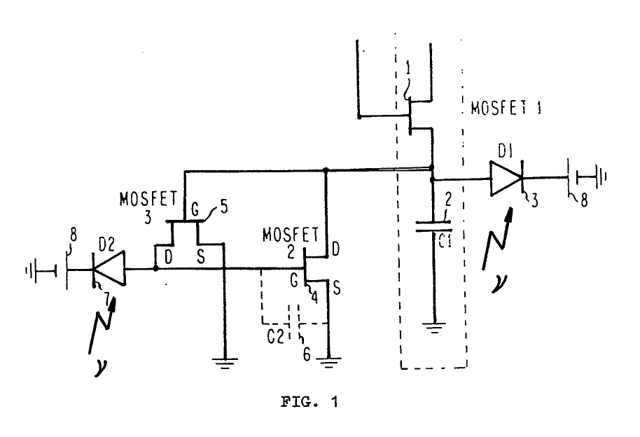

FIG. 1 shows memory cell consisting of only 3 NMOS transistors, one select transistor and two cross coupled transistors. Instead of PMOS loads two PN (P+N) photodiodes, which normally have flat reverse I/U characteristic due to large dynamic resistance, are connected as loads to drains of cross coupled transistors. Memory cell (the whole chip) is exposed to low wavelength (red) light from LED diode glued on top of chip. Introduction of light to chip surface is not completely new. In UV EPROMs UV light is used to erase memory cells through window on top of chip.

However, static cell is operated (read and write) completely different from standard 6 transistor CMOS SRAM cell. It has only one select transistor thus it operate single ended.

Write and read operation are performed similarly as in one transistor dynamic RAM cell. Read operation is particularly interesting because current is sensed by sense amplifier rather than charge (voltage change) as in DRAM cell. Precharging is also necessary for bit line. Lower voltages (compared to Vdd voltage bias −5V or 3.3 V) are used for reading (1V for word line and 0.5 V for bit line for example) and if low threshold (Vgs=0.5 V) MOS transistors are used, reading is nondestructive as in static cell. In case of reading logical “1” small discharging (reading) drain current of select transistor will be compensated by photocurrent. In case of reading logical “0” charging (reading) drain current of select transistor (Ugs=1V and decreasing, Uds=0.5V and decreasing) is compensated by drain current of MOSFET 2 which comes immediately in saturation (Vgs=5V and increasing Vds).

Photodiodes are incorporated as P+ (anodes substitute drain/source function of PMOS transistor) in N well. Thus, memory cell occupy area of 3 NMOS transistor and 1 PMOS transistor. Technology for its manufacturing is 100% standard CMOS technology.

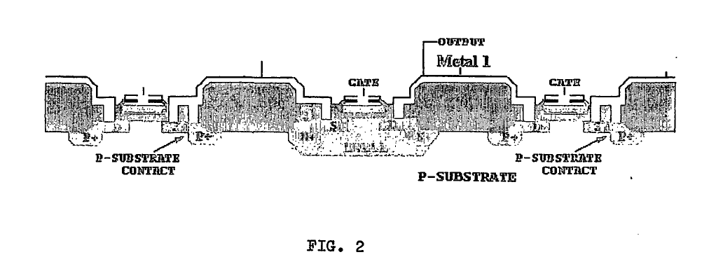

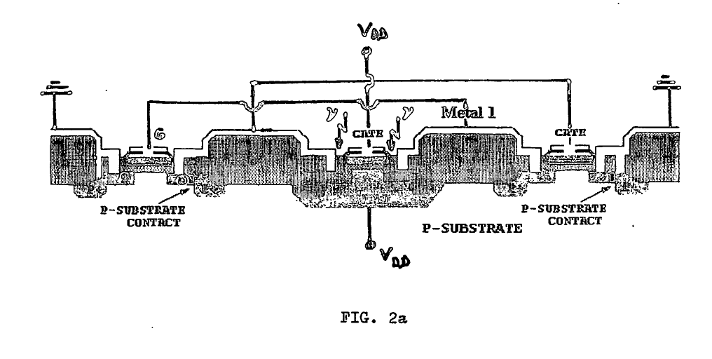

The only difference from standard 6 transistor CMOS static cell is that one select (NMOS) and one load (PMOS) transistors are removed. In remaining PMOS (load) transistor N well (N+) is connected to Vdd and P+ regions (drain and source) are connected to drains of cross-coupled NMOS transistors. When illuminated they function as load photodiodes. Metal contacts and poly(gate) are opaque to light which penetrates to P+ drain and source (photodiodes' anodes) region only, causing photocurrent, see FIG. 2a. Light penetration of low wavelength (red) light in silicon is only 1 um which corresponds with shallow and thin P+N depletion layer.

FIG. 2 shows chip cross-section incorporating classical CMOS inverter and FIG. 2a shows 2 NMOS transistors and two photodiodes connected as loads. Everything is technologycally identical except on FIG. 2a N+ is connected (metalisation) to Vdd. It is possible because N+ is shaped in a ring while P+ are squares inside it.

Gate can be left floating or connected to Vdd. Since the PMOS transistors are enhanced mode (standard CMOS) it will not operate under zero (or positive) gate-source voltage.

Aforedescribed memory cell can operate in pulsed mode. Light source can be pulsed to save energy and information will not be lost because it will be kept dynamically between two light pulses. LED diode (red) which is necessary for light input (bias) is cheap compared to the price of memory chip.

In the CMOS process, after gate oxide growth, it is preffered that the poly layer (gate) should not be deposited on P channel transistor thus leaving large transparent area for light penetration in the N well. This significantly increases photodiodes' photocurrents particularly in relation to parasitic-unwanted photocurrent which is generated in drain (N+)-substrate (P) junctions of active NMOS transistors.

It is preffered that voltage difference between word line and bit line (precharge) in reading is equal to (low) threshold voltage of (enhancement mode) NMOS transistors. Light should be scaled to generate photocurrents in photodiodes equal to drain current of NMOS transistors in saturation (Vgs=Vthreshold, Vds=Vcc).

It is possible to use standard sense (differential) amplifier which sense voltage difference between precharged bit lines because small current flow from or to the cell will slightly change voltage on connected bit line. Cell voltage (data) will not be changed. However, it is possible also to use current sense amplifier for direct sensing of read current.

What is claimed is:

1. A single ended three transistor quasi-static RAM cell comprising:
two cross coupled MOS transistors and one select MOS transistor connected to drain of one of the aforementioned MOS transistors wherein drains of both cross coupled MOS transistors are each connected to anode of one of two PN diodes functioning as loads.

2. The device of claim 1 further comprising a light source optically coupled to PN diodes, said PN diodes generating constant photocurrents due to large dynamic resistance.

3. The device of claim 2 wherein light is generated by large light emitting diode optically coupled to RAM memory chip containing aforementioned RAM cells, said light emitting diode being operated in preferably constant or pulsed mode.

4. The device of claim 1 wherein reading is performed by precharging bit line of select transistor to low voltage and word line to voltage larger for at least value of aforementioned MOS transistor threshold voltage causing small positive or negative drain current of aforementioned select transistor without changing output voltage level of cross coupled transistors representing stored data, said stored data being represented during reading by direction of drain current, said drain current being detected by current or voltage sense amplifier.

5. The device of claim 1 being manufactured by standard CMOS technology, said device being physically diferent from standard CMOS memory cell by not having one select NMOS transistor and one PMOS load transistor.

6. The device of claim 1 wherein total capacitance connected to drain of cross coupled MOS transistor connected to select MOS transistor is larger than total capacitance connected to gate of the same cross coupled transistor.
